(19) United States
(12) Patent Application Publication
(10) Pub. No.: US 2021/0289626 A1
(43) Pub. Date: Sep. 16, 2021

(54) DISPLAY DEVICE

(71) Applicant: Shenzhen Royole Technologies Co., Ltd., Shenzhen (CN)

(72) Inventors: Tsuchiang Chang, Shenzhen (CN); Shengwu Zhang, Shenzhen (CN); Jie Ni, Shenzhen (CN); Changming Qiu, Shenzhen (CN)

(21) Appl. No.: 17/336,629

(22) Filed: Jun. 2, 2021

Related U.S. Application Data
(63) Continuation of application No. PCT/CN2018/118985, filed on Dec. 3, 2018.

(51) Int. Cl. H05K 1/11; H01L 23/00; H05K 1/18

(52) U.S. Cl. CPC H05K 1/118; H01L 24/06; H05K 1/189; H05K 2201/094; H05K 2201/10128; H01L 2224/0603; H05K 2201/09418; H01L 2224/06152

(57) ABSTRACT

The present disclosure provides a display device. The display device includes a display panel and a bonding object; wherein the display panel is provided with a first bonding pad unit and a plurality of second bonding pad units respectively arranged on two sides of the first bonding pad unit, wherein a height of the first bonding pad unit in a second direction is identical to a height of the second bonding pad unit in the second direction; and the bonding object includes a third bonding pad unit corresponding to the first bonding pad unit, and fourth bonding pad units corresponding to the second bonding pad units, wherein a height of the fourth bonding pad unit in the second direction is less than a height of the third bonding pad unit in the second direction.

### CROSS-REFERENCE TO RELATED APPLICATIONS

This application is a continuation-application of International (PCT) Patent Application No. PCT/CN2018/118985, filed on Dec. 3, 2018, and entitled “Display Device,” the entire contents of which are incorporated herein by reference.

### TECHNICAL FIELD

The present disclosure relates to the technical field of electronic devices, and in particular, relates to a display device.

### BACKGROUND

Upon completion of fabrication of a display panel, an external drive chip or a flexible printed circuit (FPC) or the like needs to be connected to the display panel by heat pressing or the like. This processing is generally referred to as bonding. The external drive chip or FPC bonded to the display panel is referred to as a bonding object.

During this process, a bonding pad of the display panel is connected to a bonding pad of the bonding object, such that conduction is achieved between the display panel and the bonding object.

With respect to a flexible display panel or a flexible bonding object, an array substrate thereof is fabricated from a flexible material, and is easily subject to expansion or contraction or such deformations, for example, deformation induced by hot pressing. Therefore, problems such as large alignment errors of the bonding pads and inaccurate alignments are caused during bonding. As such, security of the bonding is poor and thus reliability is poor. When the bonding is used as a power pin, the problems even cause severe impacts.

### SUMMARY

A display device according to an embodiment of the present disclosure includes a display panel and a bonding object. The display panel is provided with a first bonding pad unit and a plurality of second bonding pad units respectively arranged on two sides of the first bonding pad unit, wherein a height of the first bonding pad unit in a second direction is identical to a height of the second bonding pad unit in the second direction. The bonding object includes a third bonding pad unit arranged corresponding to the first bonding pad unit and a plurality of fourth bonding pad units arranged corresponding to the second bonding pad units, wherein a height of the fourth bonding pad unit in the second direction is less than a height of the third bonding pad unit in the second direction, and the second direction is a direction of a reference central line of the first bonding pad unit.

A display device according to another embodiment of the present disclosure includes a display panel. The display panel is provided with a first bonding pad unit and a plurality of second bonding pad units respectively arranged on two sides of the first bonding pad unit, and a height of the first bonding pad unit in a second direction is identical to a height of the second bonding pad unit in the second direction. The first bonding pad unit is provided with a plurality of first bonding pads spaced apart along a first direction, each of the second bonding pad units is provided with a plurality of second bonding pads spaced apart along the first direction. The plurality of second bonding pad units are symmetrically arranged with respect to the first bonding pad unit, the first bonding pad unit defines a straight arrangement region, the first bonding pad is in a rectangular shape, and the plurality of first bonding pads are all parallel to the second direction; and wherein the plurality of second bonding pad units define an oblique arrangement region, the second bonding pad is in a parallelogram shape, and the plurality of second bonding pads are parallel to each other.

### BRIEF DESCRIPTION OF THE DRAWINGS

For clearer descriptions of technical solutions according to embodiments of the present application, accompanying drawings used for describing the embodiments are hereinafter briefly introduced. Apparently, the accompanying drawings hereinafter are only intended to illustrate some embodiments of the present application instead of limiting the present disclosure.

FIG. 1 is a schematic structural diagram of a display panel according to an embodiment of the present disclosure.

FIG. 2 is a schematic structural diagram of a bonding object according to an embodiment of the present disclosure.

FIG. 3 is a schematic diagram of alignment between the display panel in FIG. 1 and the bonding object in FIG. 2.

FIG. 4 is a schematic diagram of alignment by relative movement between the display panel and the bonding object along a second direction in FIG. 3.

FIG. 5 is a schematic structural diagram of a display panel according to an embodiment of the present disclosure.

FIG. 6 is a schematic structural diagram of a display panel according to an embodiment of the present disclosure.

FIG. 7 is a schematic structural diagram of a display panel according to an embodiment of the present disclosure.

FIG. 8 is a schematic structural diagram of a display panel according to an embodiment of the present disclosure.

Reference numerals and denotations thereof: 1—display panel; 11—bonding region; 2—bonding object; 3—first bonding pad unit; 31—first bonding pad; 3a—first bonding pad group; 4—second bonding pad unit; 41—second bonding pad; 5—third bonding pad unit; 51—third bonding pad; 6—fourth bonding pad unit; and 61—fourth bonding pad.

### DETAILED DESCRIPTION

For clearer descriptions of the technical features, objectives, and the technical effects of the present disclosure, the specific embodiments of the present disclosure are hereinafter described with reference to the accompanying drawings. In the description of the present disclosure, it should be understood that the terms “upper,” “lower,” “front,” “rear,” “left,” “right,” “vertical,” “horizontal,” “top,” “bottom,” “inner,” “outer” and the like indicate orientations and position relationships which are based on the illustrations in the accompanying drawings, and these terms are merely for ease and brevity of the description of the technical solutions according to the present disclosure, instead of indicating or implying that the devices or elements shall have a particular orientation and shall be structured and operated based on the particular orientation. Accordingly, these terms shall not be construed as limiting the present disclosure.

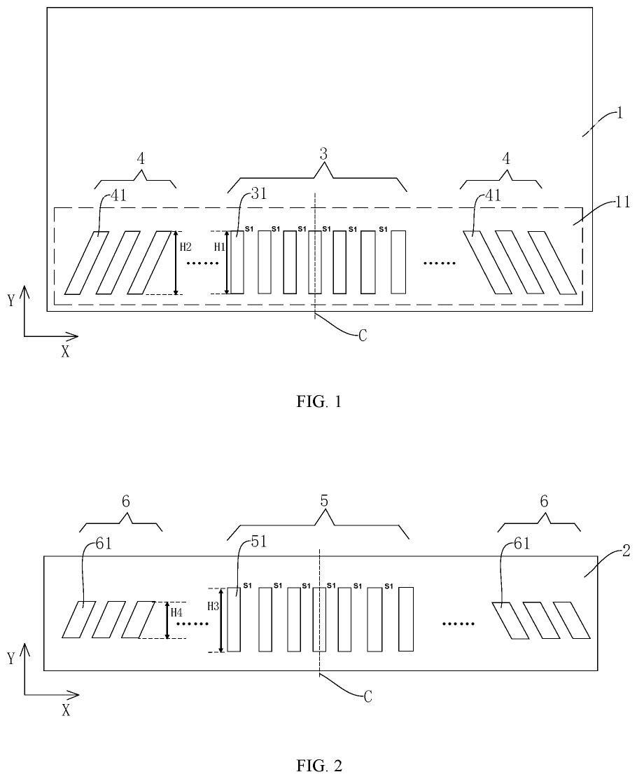

A first embodiment of the present disclosure provides a display device. As illustrated in FIG. 1 and FIG. 2, the display device includes a display panel 1, and a bonding object 2 bonded to the display panel 1.

The display panel 1 is provided with a bonding region 11 bonded with the bonding object 2. The bonding region 11 is provided with a first bonding pad unit 3 and a plurality of second bonding pad units 4 respectively arranged on two sides of the first bonding pad unit 3. The first bonding pad unit 3 is positioned in a middle region of the bonding region 11, and the plurality of bonding pad units 4 are positioned in side regions on two sides of the middle region. The plurality of second bonding pad units 4 may be symmetrically arranged with respect to the first bonding pad unit 3, and the plurality of second bonding pad units 4 may have an identical structure.

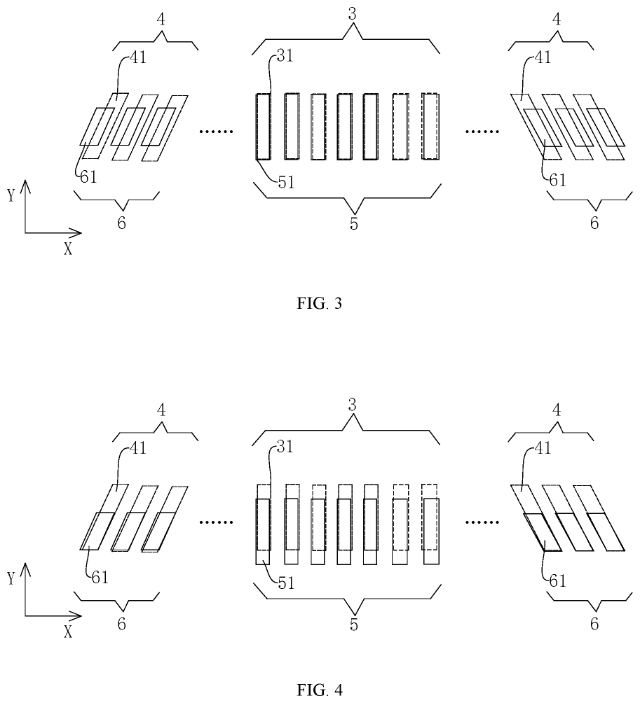

The first bonding pad unit 3 includes a plurality of first bonding pads 31 spaced apart along a first direction, and each of the second bonding pad units 4 includes a plurality of second bonding pads 41 spaced apart along the first direction. In this embodiment, the first direction may be, for example, a horizontal direction X, and the second direction may be a vertical direction Y perpendicular to the first direction, and a reference central line C is at a central position of the middle region of the bonding region 11 and is perpendicular to the first direction, that is, the reference central line C is arranged along the second direction Y. In this embodiment, the plurality of second bonding pad units 4 may be symmetrically arranged with respect to the first bonding pad unit 3. That is, the plurality of second bonding pad units 4 may be mirror symmetrically arranged with respect to the reference central line C. In this way, as illustrated in FIG. 3 and FIG. 4, during alignment, the display panel 1 and the bonding object 2 may be moved relative to each other in the second direction to be aligned with a second bonding pad 41 and a fourth bonding pad 61. In this way, even if the display panel 1 or the bonding object 2 is deformed to some extent, correct alignment may be still achieved by the relative movement during the bonding, which greatly reduces alignment errors.

In this embodiment, the first bonding pad unit 3 is configured to be a straight arrangement region, the first bonding pad 31 is a rectangular shape, the plurality of first bonding pads 31 are all parallel to the second direction, that is, an included angle defined between each of the first bonding pads 31 and the reference central line C is 0, and the plurality of first bonding pads 31 are parallel to each other. The second bonding pad units 4 are configured to be an oblique arrangement region, the second bonding pads 41 are in a parallelogram shape, each of the second bonding pads 41 defines an included angle with reference central line C, the plurality of second bonding pads 41 in each of the second bonding pad units 4 are parallel to each other, and the plurality of second bonding pad units 4 on two side regions are mirror symmetrically arranged with respect to the reference central line C. In this embodiment, a height H1 of the first bonding pad 31 in the second direction is identical to a height H2 of the second bonding pad 41 in the second direction, and the first bonding pads 31 are equally spaced apart along the first direction, that is, a spacing between any two adjacent first bonding pads 31 is S1.

During bonding of the display panel 1 in the present disclosure, the bonding object 2 bonded to the display panel 1 is further provided with bonding pads one-to-one corresponding to the bonding pads on the display panel 1. Specifically, the bonding object 2 includes a third bonding pad unit 5 corresponding to the first bonding pad unit 3, and fourth bonding pad units 6 corresponding to the second bonding pad units 4. The third bonding pad unit 5 includes a plurality of third bonding pads 51 spaced apart along the first direction, each of the fourth bonding pad units 6 includes a plurality of fourth bonding pads 61 spaced apart along the first direction, the third bonding pad unit 5 is configured to be a straight arrangement region, the third bonding pads 51 are in a rectangular shape, and the plurality of third bonding pads 51 are all parallel to the second direction, that is, an included angle defined between the each of the third bonding pad 51 and the reference central line C is 0, and the plurality of third bonding pads 51 are parallel to each other. The fourth bonding pad units 6 are configured to be an oblique arrangement region, the fourth bonding pads 61 are in a parallelogram shape, each of the fourth bonding pads 61 defines an included angle with reference central line C, the plurality of fourth bonding pads 61 in each of the fourth bonding pad units 6 are parallel to each other, and the plurality of fourth bonding pad units 6 on two side regions are mirror symmetrically arranged with respect to the reference central line C. The third bonding pads 51 are equally spaced apart along the first direction, that is, a spacing between any two adjacent third bonding pads 51 is S1, and a height H3 of the third bonding pad 51 in the second direction is greater than a height H4 of the fourth bonding pad in the second direction. The bonding pads in the bonding region are configured to be a straight arrangement region and an oblique arrangement region, the straight arrangement region is arranged at a middle position of the bonding region, the oblique arrangement area is arranged on each of two sides of the straight arrangement region, a height of the straight arrangement region on the display panel in the second direction is equal to a height of the oblique arrangement region in the second direction, and on the bonding object 2, a height of the straight arrangement region in the second direction is greater than a height of the oblique arrangement region in the second direction. As such, during bonding, a coincident area between the straight arrangement regions is greater than a coincident area between the oblique arrangement regions. The larger the coincident area during bonding, the lower the impedance, and the smaller the voltage drop and heat generation of the resistor, such that security and reliability of the bonding are improved, and the bonding is more suitable for use as a power pin. In addition, as illustrated in FIG. 3 and FIG. 4, during bonding alignment, even if the display panel 1 or the bonding object 2 is subject to deformations to some extents, the display panel 1 and the bonding object 2 may be moved relative to each other in the second direction, such that the display panel 1 and the bonding object 2 may be correctly aligned with the second bonding pad 41 and the fourth bonding pad 61.

Optionally, since an alignment error in the middle region of the bonding region is the minimum, pre-compensation may be made on the display panel 1 or the bonding object 2. In this way, after the display panel 1 or the bonding object 2 is deformed, the corresponding bonding pads thereof may be correctly aligned, and thus the alignment errors are greatly reduced.

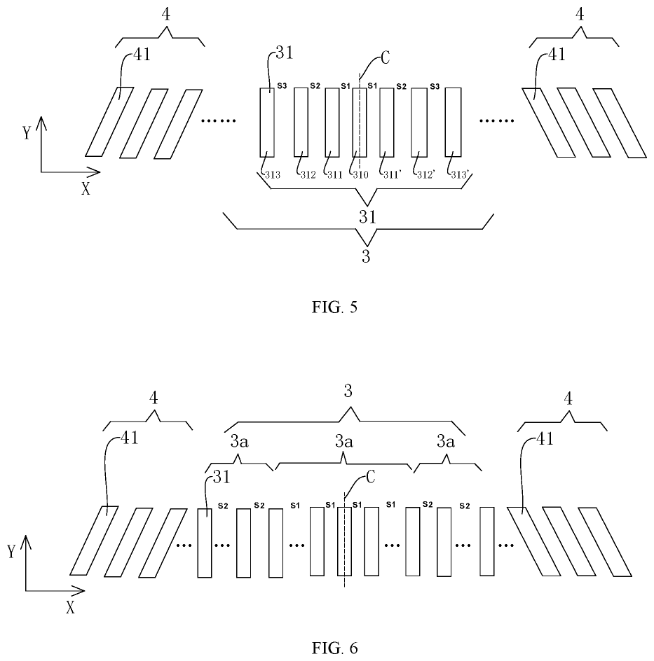

A second embodiment is as illustrated in FIG. 5. The technical solution of the display panel 1 in this embodiment is different from that in the above embodiments.

In this embodiment, the display panel 1 is provided with a bonding region 11 bonded to the bonding object 2. The bonding region 11 is provided with a first bonding pad unit 3 and a plurality of second bonding pad units 4 arranged on two sides of the first bonding pad unit 3. The first bonding pad unit 3 is positioned in a middle region of the bonding region 11, and the plurality of second bonding pad units 4 are positioned in side regions on two sides of the middle region. The plurality of second bonding pad units 4 may be symmetrically arranged with respect to the first bonding pad unit 3, and the plurality of second bonding pad units 4 may have an identical structure.

The first bonding pad unit 3 includes a plurality of first bonding pads 31 spaced apart along a first direction, and each of the second bonding pad units 4 includes a plurality of second bonding pads 41 spaced apart along the first direction. In this embodiment, the first direction may be, for example, a horizontal direction X, and the second direction may be a vertical direction Y perpendicular to the first direction, and a reference central line C is at a central position of the middle region of the bonding region 11 and is perpendicular to the first direction, that is, the reference central line C is arranged along the second direction Y. In this embodiment, the plurality of second bonding pad units 4 may be symmetrically arranged with respect to the first bonding pad unit 3. That is, the plurality of second bonding pad units 4 may be mirror symmetrically arranged with respect to the reference central line C.

In this embodiment, the first bonding pad unit 3 is configured to be a straight arrangement region, the first bonding pad 31 is a rectangular shape, the plurality of first bonding pads 31 are all parallel to the second direction, that is, an included angle defined between each of the first bonding pads 31 and the reference central line C is 0, and the plurality of first bonding pads 31 are parallel to each other. The second bonding pad units 4 are configured to be an oblique arrangement region, the second bonding pads 41 are in a parallelogram shape, each of the second bonding pads 41 defines an included angle with reference central line C, the plurality of second bonding pads 41 in each of the second bonding pad units 4 are parallel to each other, and the plurality of second bonding pad units 41 on two side regions are mirror symmetrically arranged with respect to the reference central line C. In this embodiment, an identical spacing is defined between any two adjacent first bonding pads 31 symmetrical with respect to the reference central line C, a different spacing is defined between any two adjacent first bonding pads on a same side of the reference central line C. For example, as illustrated in FIG. 5, a first bonding pad 310 is on the reference central line C, first bonding pads 311 and 311′, first bonding pads 312 and 312′, and first bonding pads 313 and 313′ are respectively symmetrical with respect to the reference central line C, a spacing between the first bonding pads 311 and 310 and a spacing between the first bonding pads 311′ and 310 are both S1, a spacing between the first bonding pads 311 and 312 and a spacing between the first bonding pads 311′ and 312′ are both S2, and a spacing between the first bonding pads 312 and 313 and a spacing between the first bonding pads 312′ and 313′ are both S3, wherein S1≠S2≠S3. In this way, the spacing between the first bonding pads 31 may be defined according to deformation degrees at different positions of the display panel 1 or the bonding object 2, such that a pre-compensation effect is achieved. Therefore, during bonding to the bonding object 2, after the display panel 1 or the bonding object 2 is deformed, the first bonding pads 31 and the third bonding pads 51 may be correspondingly aligned, which greatly reduces alignment errors.

A common deformation of the display panel 1 or the bonding object 2 is that a position far away from the reference central line C has a greater deformation amount. With respect to this circumstance, the display panel 1 in this embodiment may be further configured such that the farther away from the reference central line C, the greater the spacing between two adjacent first bonding pads 31. As illustrated in FIG. 5, S1<S2<S3.

The configuration of the bonding object 2 in this embodiment may be the same as the configuration in the first embodiment.

A third embodiment is as illustrated in FIG. 6. The technical solution of the display panel 1 in this embodiment is different from that in the above embodiments.

In this embodiment, the display panel 1 is provided with a bonding region 11 bonded to the bonding object 2. The bonding region 11 is provided with a first bonding pad unit 3 and a plurality of second bonding pad units 4 arranged on two sides of the first bonding pad unit 3. The first bonding pad unit 3 is positioned in a middle region of the bonding region 11, and the plurality of second bonding pad units 4 are positioned in side regions on two sides of the middle region. The plurality of second bonding pad units 4 may be symmetrically arranged with respect to the first bonding pad unit 3, and the plurality of second bonding pad units 4 may have an identical structure.

The first bonding pad unit 3 includes a plurality of first bonding pads 31 spaced apart along a first direction, and each of the second bonding pad units 4 includes a plurality of second bonding pads 41 spaced apart along the first direction. In this embodiment, the first direction may be, for example, a horizontal direction X, and the second direction may be a vertical direction Y perpendicular to the first direction, and a reference central line C is at a central position of the middle region of the bonding region 11 and is perpendicular to the first direction, that is, the reference central line C is arranged along the second direction Y. In this embodiment, the plurality of second bonding pad units 4 may be symmetrically arranged with respect to the first bonding pad unit 3. That is, the plurality of second bonding pad units 4 may be mirror symmetrically arranged with respect to the reference central line C.

In this embodiment, the first bonding pad unit 3 is configured to be a straight arrangement region, the first bonding pad 31 is a rectangular shape, the plurality of first bonding pads 31 are all parallel to the second direction, that is, an included angle defined between each of the first bonding pads 31 and the reference central line C is 0, and the plurality of first bonding pads 31 are parallel to each other. The second bonding pad units 4 are configured to be an oblique arrangement region, the second bonding pads 41 are in a parallelogram shape, each of the second bonding pads 41 defines an included angle with reference central line C, the plurality of second bonding pads 41 in each of the second bonding pad units 4 are parallel to each other, and the plurality of second bonding pad units 4 on two side regions are mirror symmetrically arranged with respect to the reference central line C. In this embodiment, the first bonding pad unit 3 includes a plurality of first bonding pad groups 3a; wherein each of the first bonding pad groups 3a includes at least two of the first bonding pads 31, an identical spacing is defined between any adjacent two of the first bonding pads 31 in a same first bonding pad group 3a, and a different spacing is defined between any adjacent two of the first bonding pads 31 in a different first bonding pad group 3a on a same side of the reference central line C. For example, as illustrated in FIG. 6, on the same side of the reference central line C, the spacings between any two adjacent first bonding pads 31 in two different first bonding pad groups 3a are respectively S1 and S2, wherein S1≠S2. In this way, the spacing between two adjacent first bonding pads 31 in each of the first bonding pad groups 3a may be defined according to deformation degrees at different positions of the display panel 1 or the bonding object 2, such that a pre-compensation effect is achieved. Therefore, during bonding to the bonding object 2, after the display panel 1 or the bonding object 2 is deformed, the first bonding pads 31 and the third bonding pads 51 may be correspondingly aligned, which greatly reduces alignment errors.

Further, a common deformation of the display panel 1 or the bonding object 2 is that a position far away from the reference central line C has a greater deformation amount. With respect to this circumstance, the display panel 1 in this embodiment may be further configured such that, on the same side of the reference central line C, in a first bonding pad group 3a farther away from the reference central line C, a greater spacing is defined between two adjacent first bonding pads 31. As illustrated in FIG. 6, S1<S2.

The configuration of the bonding object 2 in this embodiment may be the same as the configuration in the first embodiment.

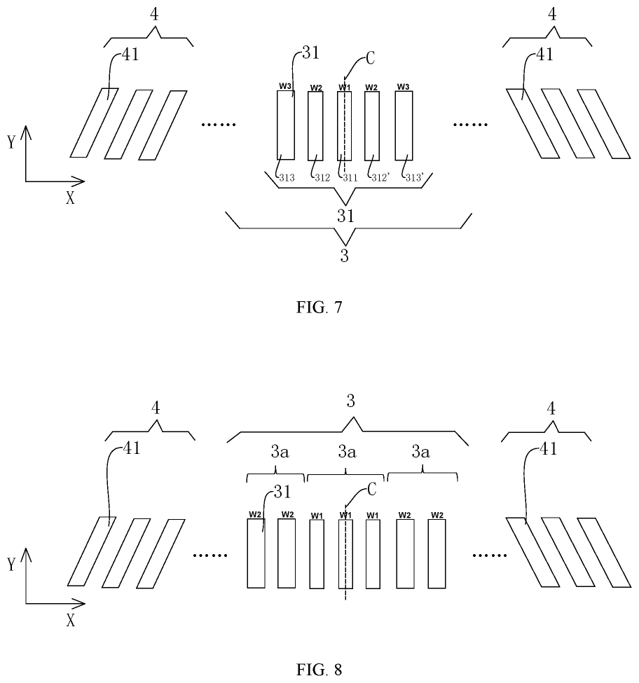

A fourth embodiment is as illustrated in FIG. 7. The technical solution of the display panel 1 in this embodiment is different from that in the above embodiments.

In this embodiment, the display panel 1 is provided with a bonding region 11 bonded to the bonding object 2. The bonding region 11 is provided with a first bonding pad unit 3 and a plurality of second bonding pad units 4 arranged on two sides of the first bonding pad unit 3. The first bonding pad unit 3 is positioned in a middle region of the bonding region 11, and the plurality of second bonding pad units 4 are positioned in side regions on two sides of the middle region. The plurality of second bonding pad units 4 may be symmetrically arranged with respect to the first bonding pad unit 3, and the plurality of second bonding pad units 4 may have an identical structure.

The first bonding pad unit 3 includes a plurality of first bonding pads 31 spaced apart along a first direction, and each of the second bonding pad units 4 includes a plurality of second bonding pads 41 spaced apart along the first direction. In this embodiment, the first direction may be, for example, a horizontal direction X, and the second direction may be a vertical direction Y perpendicular to the first direction, and a reference central line C is at a central position of the middle region of the bonding region 11 and is perpendicular to the first direction, that is, the reference central line C is arranged along the second direction Y. In this embodiment, the plurality of second bonding pad units 4 may be symmetrically arranged with respect to the first bonding pad unit 3. That is, the plurality of second bonding pad units 4 may be mirror symmetrically arranged with respect to the reference central line C.

In this embodiment, the first bonding pad unit 3 is configured to be a straight arrangement region, the first bonding pad 31 is a rectangular shape, the plurality of first bonding pads 31 are all parallel to the second direction, that is, an included angle defined between each of the first bonding pads 31 and the reference central line C is 0, and the plurality of first bonding pads 31 are parallel to each other. The second bonding pad units 4 are configured to be an oblique arrangement region, the second bonding pads 41 are in a parallelogram shape, each of the second bonding pads 41 defines an included angle with reference central line C, the plurality of second bonding pads 41 in each of the second bonding pad units 4 are parallel to each other, and the plurality of second bonding pad units 4 on two side regions are mirror symmetrically arranged with respect to the reference central line C. The plurality of first bonding pads 31 may have an identical width along the first direction (for example, as illustrated in FIG. 7, W1=W2=W3), or may have different widths to achieve a pre-compensation effect. To be specific, when the plurality of first bonding pads 31 have different widths along the first direction, the first bonding pads 31 symmetrical with respect to the reference central line C have an identical width along the first direction, the first bonding pads 31 on the same side of the reference central line C have different widths along the first direction. For example, as illustrated in FIG. 7, the first bonding pad 311 is on the reference central line C, the first bonding pads 312 and 312′ are symmetrical with respect to the reference central line C, the first bonding pads 313 and 313′ are symmetrical with respect to the reference central line C, the first bonding pad 311 have a width of W1, the first bonding pads 312 and 312′ both have a width of W2, and the first bonding pads 313 and 313′ both have a width of W3, wherein W1≠W2≠W3. In this way, the width of each of the first bonding pads 31 along the first direction may be defined according to deformation degrees at different positions of the display panel 1 or the bonding object 2, such that a pre-compensation effect is achieved. Therefore, during bonding to the bonding object 2, after the display panel 1 or the bonding object 2 is deformed, the first bonding pads 31 and the third bonding pads 51 may be correspondingly aligned, which greatly reduces alignment errors.

A common deformation of the display panel 1 or the bonding object 2 is that a position far away from the reference central line C has a greater deformation amount. With respect to this circumstance, the display panel 1 in this embodiment may be further configured such that the farther away from the reference central line C, the greater the width of the first bonding pad 31. As illustrated in FIG. 7, W1<W2<W3.

The configuration of the bonding object 2 in this embodiment may be the same as the configuration in the first embodiment.

A fifth embodiment is as illustrated in FIG. 8. The technical solution of the display panel 1 in this embodiment is different from that in the above embodiments.

In this embodiment, the display panel 1 is provided with a bonding region 11 bonded to the bonding object 2. The bonding region 11 is provided with a first bonding pad unit 3 and a plurality of second bonding pad units 4 arranged on two sides of the first bonding pad unit 3. The first bonding pad unit 3 is positioned in a middle region of the bonding region 11, and the plurality of second bonding pad units 4 are positioned in side regions on two sides of the middle region. The plurality of second bonding pad units 4 may be symmetrically arranged with respect to the first bonding pad unit 3, and the plurality of second bonding pad units 4 may have an identical structure.

The first bonding pad unit 3 includes a plurality of first bonding pads 31 spaced apart along a first direction, and each of the second bonding pad units 4 includes a plurality of second bonding pads 41 spaced apart along the first direction. In this embodiment, the first direction may be, for example, a horizontal direction X, and the second direction may be a vertical direction Y perpendicular to the first direction, and a reference central line C is at a central position of the middle region of the bonding region 11 and is perpendicular to the first direction, that is, the reference central line C is arranged along the second direction Y. In this embodiment, the plurality of second bonding pad units 4 may be symmetrically arranged with respect to the first bonding pad unit 3. That is, the plurality of second bonding pad units 4 may be mirror symmetrically arranged with respect to the reference central line C.

In this embodiment, the first bonding pad unit 3 is configured to be a straight arrangement region, the first bonding pad 31 is a rectangular shape, the plurality of first bonding pads 31 are all parallel to the second direction, that is, an included angle defined between each of the first bonding pads 31 and the reference central line C is 0, and the plurality of first bonding pads 31 are parallel to each other. The second bonding pad units 4 are configured to be an oblique arrangement region, the second bonding pads 41 are in a parallelogram shape, each of the second bonding pads 41 defines an included angle with reference central line C, the plurality of second bonding pads 41 in each of the second bonding pad units 4 are parallel to each other, and the plurality of second bonding pad units 4 on two side regions are mirror symmetrically arranged with respect to the reference central line C. In this embodiment, the first bonding pad unit 3 includes a plurality of first bonding pad groups 3a; wherein each of the first bonding pad groups 3a includes at least two of the first bonding pads 31, the first bonding pads 31 in a same first bonding pad group 3a have an identical width along the first direction, and the first bonding pads 31 in different first bonding pad groups 3a on a same side of the reference central line C have different widths along the first direction. For example, as illustrated in FIG. 8, the widths of the first bonding pads 31 in the first bonding pad group 3a on the reference central line are all W1, and on the same side of the reference central line C, the widths of the first bonding pads 31 in two different bonding pad groups 3a are respectively W1 and W2, wherein W1≠W2. In this way, the width of the first bonding pad 31 in each of the first bonding pad group 3a may be defined according to deformation degrees at different positions of the display panel 1 or the bonding object 2, such that a pre-compensation effect is achieved. Therefore, during bonding to the bonding object 2, after the display panel 1 or the bonding object 2 is deformed, the first bonding pads 31 and the third bonding pads 51 may be correspondingly aligned, which greatly reduces alignment errors.

A common deformation of the display panel 1 or the bonding object 2 is that a position far away from the reference central line C has a greater deformation amount. With respect to this circumstance, the display panel 1 in this embodiment may be further configured such that the width of the first bonding pad 31 in the first bonding pad group 3a farther away from the reference central line C is greater. As illustrated in FIG. 8, W1<W2.

The configuration of the bonding object 2 in this embodiment may be the same as the configuration in the first embodiment.

In the above various embodiments, the spacing configuration and the width configuration of the first bonding pads 31 may be in combination. For example, the spacing configuration of the first bonding pads 31 in the second or third embodiment, and the width configuration of the first bonding pads 31 in the fourth or fifth embodiment may be combined on the display panel 1 in practice.

In summary, in the display device according to the present disclosure, during bonding, a coincident area between the straight arrangement regions is greater than a coincident area between the oblique arrangement regions. The larger the coincident area during bonding, the lower the impedance, and the smaller the voltage drop and heat generation of the resistor, such that security and reliability of the bonding are improved, and the bonding is more suitable for use as a power pin. In addition, the bonding pads in the bonding region are configured to be a straight arrangement region and an oblique arrangement region, the straight arrangement region is arranged at a middle position of the bonding region, the oblique arrangement area is arranged on each of two sides of the straight arrangement region, a height of the straight arrangement region on the display panel in the second direction is equal to a height of the oblique arrangement region in the second direction, and on the bonding object 2, a height of the straight arrangement region in the second direction is greater than a height of the oblique arrangement region in the second direction. As such, during bonding, even if the display panel 1 or the bonding object 2 is subject to deformations to some extents, the display panel 1 and the bonding object 2 may be moved relative to each other in the second direction, such that the display panel 1 and the bonding object 2 may be correctly aligned with the second bonding pad 41 and the fourth bonding pad 61. Further, the spacings between the first bonding pads 31 may be totally identical or not totally identical to each other, and the widths of the first bonding pads 31 may be totally identical or not totally identical to each other, to achieve a pre-compensation effect. Therefore, during bonding to the bonding object 2, after the display panel 1 or the bonding object 2 is deformed, the corresponding first bonding pads 31 and third bonding pads 51 thereof may be correctly aligned, and thus the alignment errors are greatly reduced.

The bonding objects 2 in this text may be different under different bonding situations, for example, an external drive chip or an FPC, a corresponding bonding structure such as a chip-on-film (COF) in a COF process, a corresponding bonding structure in a chip-on-glass (COG) process.

Described above are merely preferred embodiments of the present disclosure, but are not intended to limit the present disclosure. A person skilled in the art may derive various modifications and variations of the present disclosure. Any modification, equivalent replacement, and improvement made without departing from the spirit and principle of the present disclosure shall fall within the protection scope of the present disclosure.

What is claimed is:

1. A display device, comprising a display panel and a bonding object;
wherein the display panel is provided with a first bonding pad unit and a plurality of second bonding pad units respectively arranged on two sides of the first bonding pad unit, and a height of the first bonding pad unit in a second direction is identical to a height of the second bonding pad unit in the second direction; and
wherein the bonding object comprises a third bonding pad unit arranged corresponding to the first bonding pad unit and a plurality of fourth bonding pad units arranged corresponding to the second bonding pad units a height of the fourth bonding pad unit in the second direction is less than a height of the third bonding pad unit in the second direction, and the second direction is a direction of a reference central line of the first bonding pad unit.

2. The display device according to claim 1, wherein the first bonding pad unit is provided with a plurality of first bonding pads spaced apart along a first direction, each of the second bonding pad units is provided with a plurality of second bonding pads spaced apart along the first direction, the third bonding pad unit is provided with a plurality of third bonding pads spaced apart along the first direction, each of the fourth bonding pad units is provided with a plurality of fourth bonding pads spaced apart along the first direction, and the first direction is perpendicular to the second direction.

3. The display device according to claim 2, wherein the plurality of second bonding pad units are symmetrically arranged with respect to the first bonding pad unit the first bonding pad unit defines a straight arrangement region, the first bonding pad is in a rectangular shape, and the plurality of first bonding pads are all parallel to the second direction; and wherein the plurality of second bonding pad units define an oblique arrangement region, the second bonding pad is in a parallelogram shape, and the plurality of second bonding pads are parallel to each other.

4. The display device according to claim 3, wherein the plurality of first bonding pads are equally spaced apart along the first direction.

5. The display device according to claim 3, wherein an identical spacing is defined between any adjacent two of the first bonding pads symmetrical with respect to the reference central line, and a different spacing is defined between any adjacent two of the first bonding pads on a same side of the reference central line.

6. The display device according to claim 3, wherein the first bonding pad unit comprises a plurality of first bonding pad groups; and wherein each of the first bonding pad groups comprises at least two of the first bonding pads, an identical spacing is defined between any adjacent two of the first bonding pads in a same first bonding pad group, and a different spacing is defined between any adjacent two of the first bonding pads in different first bonding pad groups on a same side of the reference central line.

7. The display device according to claim 3, wherein the plurality of first bonding pads have an identical width along the first direction.

8. The display device according to claim 3, wherein the first bonding pads symmetrical with respect to the reference central line have an identical width along the first direction, and the first bonding pads on a same side of the reference central line have different widths along the first direction.

9. The display device according to claim 3, wherein the first bonding pad unit comprises a plurality of first bonding pad groups; and wherein each of the first bonding pad groups comprises at least two of the first bonding pads, the first bonding pads in a same first bonding pad group have an identical width along the first direction, and the first bonding pads in different first bonding pad groups on a same side of the reference central line have different widths along the first direction.

10. The display device according to claim 3, wherein the plurality of fourth bonding pad units are symmetrically arranged with respect to the third bonding pad unit the third bonding pad unit defines a straight arrangement region, the third bonding pad is a rectangular shape, and the plurality of third bonding pads are all parallel to the second direction; and the plurality of fourth bonding pad units define an oblique arrangement region, the fourth bonding pad is in a parallelogram shape, and the plurality of fourth bonding pads are parallel to each other.

11. The display device according to claim 1, wherein the display panel is a flexible display panel.

12. The display device according to claim 1, wherein the bonding object is a flexible bonding object.

13. A display device, comprising a display panel;
wherein the display panel is provided with a first bonding pad unit and a plurality of second bonding pad units respectively arranged on two sides of the first bonding pad unit and a height of the first bonding pad unit in a second direction is identical to a height of the second bonding pad unit in the second direction;
wherein the first bonding pad unit is provided with a plurality of first bonding pads spaced apart along a first direction, each of the second bonding pad units is provided with a plurality of second bonding pads spaced apart along the first direction; and
wherein the plurality of second bonding pad units are symmetrically arranged with respect to the first bonding pad unit the first bonding pad unit defines a straight arrangement region, the first bonding pad is in a rectangular shape, and the plurality of first bonding pads are all parallel to the second direction; and wherein the plurality of second bonding pad units define an oblique arrangement region, the second bonding pad is in a parallelogram shape, and the plurality of second bonding pads are parallel to each other.

14. The display device according to claim 13, wherein the plurality of first bonding pads are equally spaced apart along the first direction.

15. The display device according to claim 13, wherein an identical spacing is defined between any adjacent two of the first bonding pads symmetrical with respect to the reference central line, and a different spacing is defined between any adjacent two of the first bonding pads on a same side of the reference central line.

16. The display device according to claim 13, wherein the first bonding pad unit comprises a plurality of first bonding pad groups; and wherein each of the first bonding pad groups comprises at least two of the first bonding pads, an identical spacing is defined between any adjacent two of the first bonding pads in a same first bonding pad group, and a different spacing is defined between any adjacent two of the first bonding pads in different first bonding pad groups on a same side of the reference central line.

17. The display device according to claim 13, wherein the plurality of first bonding pads have an identical width along the first direction.

18. The display device according to claim 13, wherein the first bonding pads symmetrical with respect to the reference central line have an identical width along the first direction, and the first bonding pads on a same side of the reference central line have different widths along the first direction.

19. The display device according to claim 13, wherein the first bonding pad unit comprises a plurality of first bonding pad groups; and wherein each of the first bonding pad groups comprises at least two of the first bonding pads, the first bonding pads in a same first bonding pad group have an identical width along the first direction, and the first bonding pads in different first bonding pad groups on a same side of the reference central line have different widths along the first direction.
